(19) United States
(12) Patent Application Publication
(10) Pub. No.: US 2007/0014089 A1
(43) Pub. Date: Jan. 18, 2007

(54) Radiator unit for an electronic component

(76) Inventor: Jia-Lie Huang, Taipei (TW)

Correspondence Address: G. LINK Co., LTD, 3550 Bell Road, Minooka, IL, 60447, US

(21) Appl. No.: 11/182,931

(22) Filed: Jul. 18, 2005

(51) Int. Cl. H05K 7/20

(52) U.S. Cl. 361/695

(57) ABSTRACT

A radiator unit for an electronic component includes a main member and cooling fins. Each of the cooling fins has a first end connecting with the perimeter of the main member and a second end extending outward in a radial direction with the thickness thereof being different from the first end to the second end. Heat of the electronic component is dissipated with the aid of the main member and the cooling fins.

### BACKGROUND OF THE INVENTION

1. Field of the Invention

The present invention is related to a radiator unit for an electronic component and particularly to a radiator in which the cooling fins provide different thicknesses.

2. Brief Description of the Related Art

The technology of fabricating electronic components with lightness, shortness, smallness and thinness is the current trend of research and development. The structural design of electronic equipment with compactness is a pursued trend too. Under this circumference, the loaded heat of unit volume increases and it is required to design the electronic components with most economical cost for sending heat thereof out effectively so as to secure reliability and life span of the electronic components. The most popular way of heat dissipation for the electronic components is a radiator with a fan is attached to the each of the electronic components. The heat generated by the respective electronic component is capable of transmit to the radiator and being removed by way of the fan blowing the air passing through the surface of the radiator. Therefore, material and size of the radiator significantly influence effect of convection and capability of heat dissipation.

Especially for the CPU (Central Processing Unit) of a computer, it is required very much to avoid phenomena such as overheat, short circuit and even burned out chip with effective way of heat removal in order to promote operation speed and capability of a chip and to increase power of the chip. Therefore, design of radiator is extremely important for electronic equipment so that it is a vital subject to find out cooling fins with minimum sizes and maximum heat transfer quantity under known restrictions.

Referring to FIGS. 1 to 3, the first type conventional radiator has a main member 11 and a plurality of cooling fins 12. Each of the cooling fins 12 extends along the perimeter of the main member 11 and the cooling fins 32 space apart a flow passage 123 to each other respectively. Each of the cooling fins 32 has a first end 121 connects with the perimeter of the main member 11 and a second end 122, which is the outer end extending outward. The thickness is kept the same from the first end 121 to the second end 122, that is, each of the cooling fins 12 is flat as shown in FIG. 3.

Referring to FIGS. 4, 5 and 6, a fan 14 is joined to the main member 11 for applying to an electronic component 13. It can be seen that the bottom of the main member 11 is attached to the surface of the electronic component 13 and the fan 14 is fixed to the top of the main member 11. The main member 11 conducts heat generated by the electronic component 13 to the cooling fins 12 and the fan 14 induces cold air to move toward the radiator. Once the cold air moves along the flow passage 123 between respective cooling fins 12, the cold air contacts with the surface of each of the cooling fins 12 to perform heat exchange with the heat transmitted by the cooling fins 12. When the air leaves the radiator to flow outward, the heat is carried with the air to reduce heat from the electronic component 13.

Referring to FIGS. 7 to 9, the second type conventional radiator is illustrated. The integral structure is about the same as the preceding conventional radiator and the minor difference of the second type conventional radiator is in that each of the cooling fins 22 has a slight curve from the first end 221 to the second end 222 with the same thickness. That is, each of the cooling fins is a bent plate as shown in FIG. 9.

The problem of preceding two conventional radiators in use is thickness of the first end 121, 221 to the second end 221, 222 of each of the cooling fins 12, 22 is kept the same regardless it is flat as the first conventional radiator or the bent as the second conventional radiator. When the fan 14 induces fluid to enter the flow passages between the cooling fins 12, 22 axially, flow resistance value too large to allow the fluid moving outward via the flow passages 123, 223, i.e., the thermal flow is small. Further, it results in high thermal resistance such that it is incapable of bringing heat generated by the electronic component 13 out effectively and it reduces life span of the electronic component 13 due to temperature rise.

Besides, the preceding problem exists in Taiwanese Design Patent Nos. 596345 “RADIATOR (3) and 596346 “RADIATOR (1)”.

Further, Taiwanese Design Patent No. 596350 “RADIATOR” discloses several pieces of bent cooling fins are at the center of the radiator and a plurality of flat cooling fins are radially disposed around the center. The central hub of a fan is disposed above the bent cooling fins such that fluid induced by the fan is incapable of flowing to the center of the radiator and it only flows to the flat cooling fins. The preceding problem is still occurred in Taiwanese Design Patent No. 596350.

### SUMMARY OF THE INVENTION

In order to solve the preceding problems residing in the conventional device, an object of the present invention is to provide a radiator unit for an electronic component in which each of the cooling fins provides different thicknesses from the first end to the second end to allow fluid flowing smoothly so as to increase thermal energy and lower flow resistance and thermal resistance of the radiator.

Another object of the present invention is to provide a radiator unit for an electronic component in which each of the cooling fins is bent from the first end to the second end thereof so as to decrease noise resulting from impact of the fluid to the cooling fins.

A further object of the present invention is to provide a radiator unit for an electronic component in which each of the cooling fins provides different thicknesses from the first end to the second thereof to increase the number of the cooling fins such that it increases heat dissipation area.

In order to achieve the preceding objects, the radiator unit for an electronic component according to the present invention includes a main member and cooling fins. Each of the cooling fins has a first end connecting with the perimeter of the main member and a second end extending outward in a radial direction with the thickness thereof being different from the first end to the second end.

The radiator unit of the second aspect includes a main member, providing at least a first side and a second side opposite to the second side; and a plurality of cooling fins, being mounted to the first side, each of the cooling fins having a first end and a second end opposite to the first end with the thickness thereof being different from the first end to the second end.

### BRIEF DESCRIPTION OF THE DRAWINGS

The detail structure, the applied principle, the function and the effectiveness of the present invention can be more fully understood with reference to the following description and accompanying drawings, in which:

FIG. 1 is top view of the conventional radiator;

FIG. 2 is a perspective view of the conventional radiator;

FIG. 3 is a plan view of a cooling fin in the conventional radiator;

FIG. 4 is an exploded perspective view illustrating the conventional radiator in association with a fan being applied to an electronic component;

FIG. 5 is an assembled front view of FIG. 4;

FIG. 6 is a top view of FIG. 5;

FIG. 7 is a top view of the second type conventional radiator;

FIG. 8 is a perspective view of the second type conventional radiator;

FIG. 9 is a plan view of a cooling fin in the second type conventional radiator;

FIG. 10 is a top view of the first embodiment of a radiator unit for electronic components according to the present invention;

FIG. 11 is a perspective view of the first embodiment of a radiator unit for electronic components according to the present invention;

FIG. 12 is a plan view of the first configuration of a cooling fin in the first embodiment of the present invention;

FIG. 13 is a plan view of the second configuration of a cooling fin in the first embodiment of the present invention;

FIG. 14 is an exploded perspective view illustrating the radiator unit in the first embodiment of the present invention in association with a fan being applied to an electronic component;

FIG. 15 is an assembled front view of FIG. 14;

FIG. 16 is a top view of FIG. 15;

FIG. 17 is a top view of the second embodiment of a radiator unit for electronic components according to the present invention;

FIG. 18 is a perspective view of the second embodiment of a radiator unit for electronic components according to the present invention;

FIG. 19 is a top view of the third embodiment of a radiator unit for electronic components according to the present invention;

FIG. 20 is a perspective view of the third embodiment of a radiator unit for electronic components according to the present invention;

FIG. 21 is a plan view of the first configuration of a cooling fin in the first embodiment of the present invention;

FIG. 22 is a plan view of the second configuration of a cooling fin in the third embodiment of the present invention;

FIG. 23 is an exploded perspective view illustrating the radiator unit in the third embodiment of the present invention in association with a fan being applied to an electronic component;

FIG. 24 is a an assembled front view of FIG. 23;

FIG. 25 is a top view of FIG. 24;

FIG. 26 is a top view of another arrangement of the cooling fins in the third embodiment of the present invention; and

FIG. 27 is a perspective view illustrating another arrangement of the cooling fins in the third embodiment of the present invention;

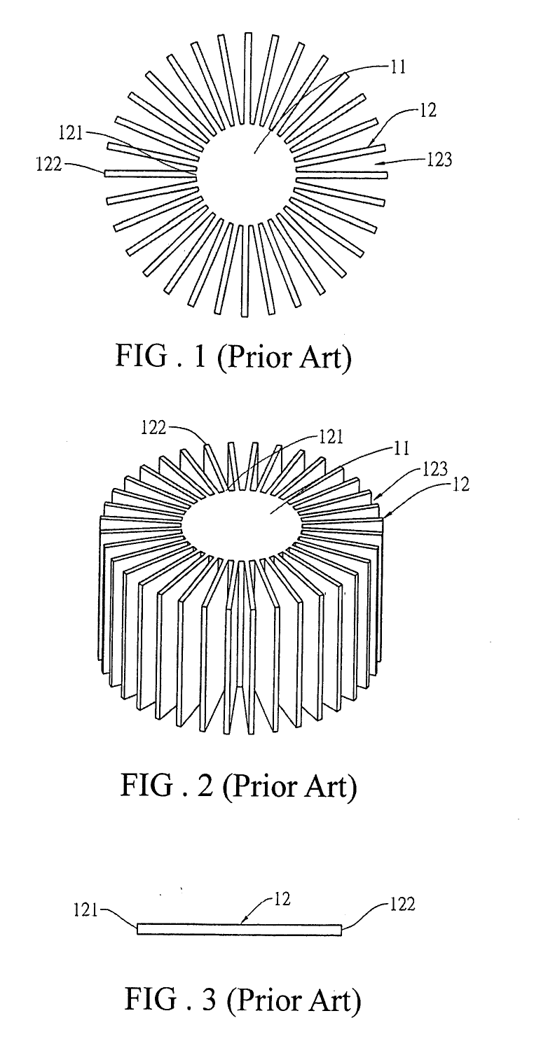

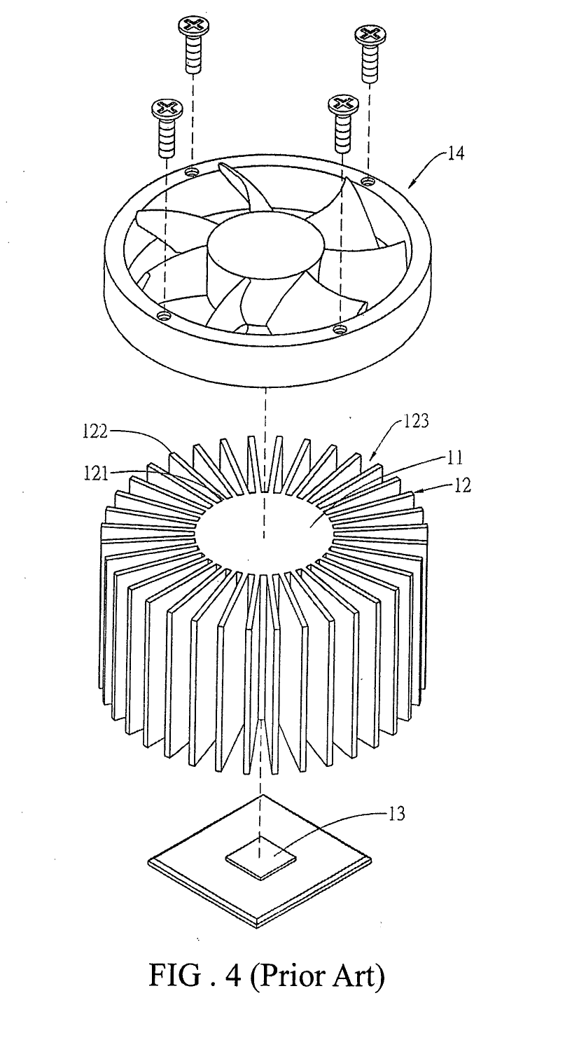

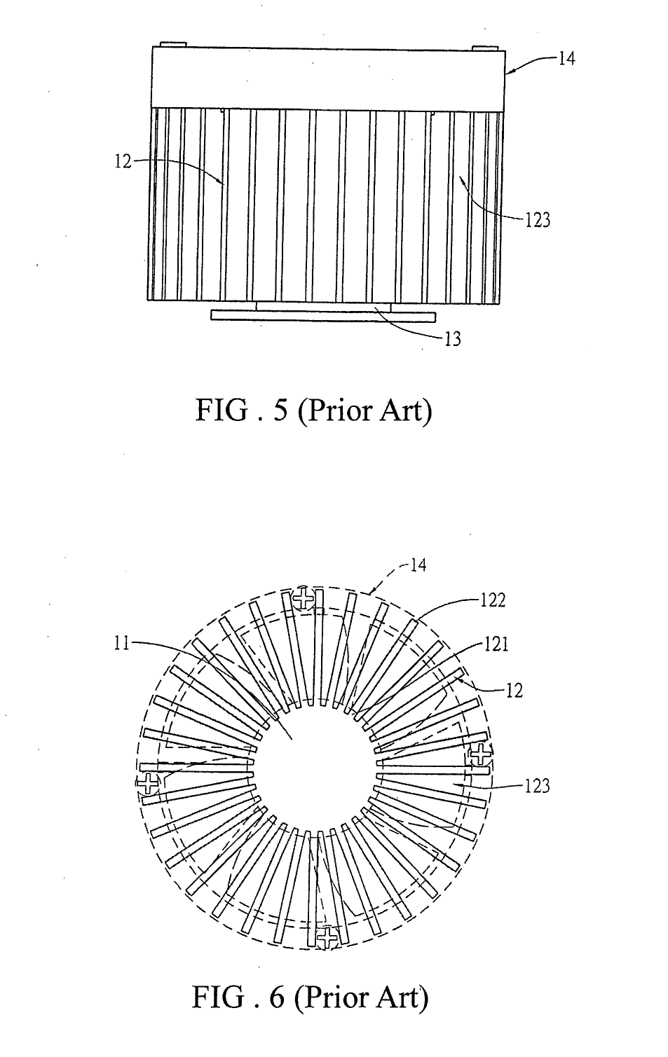

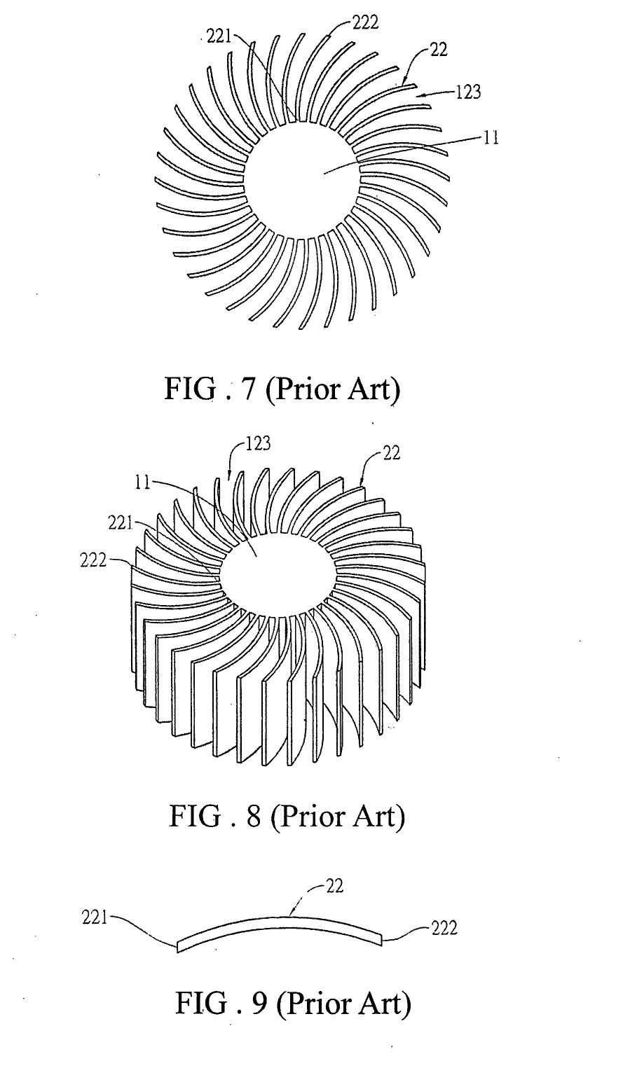

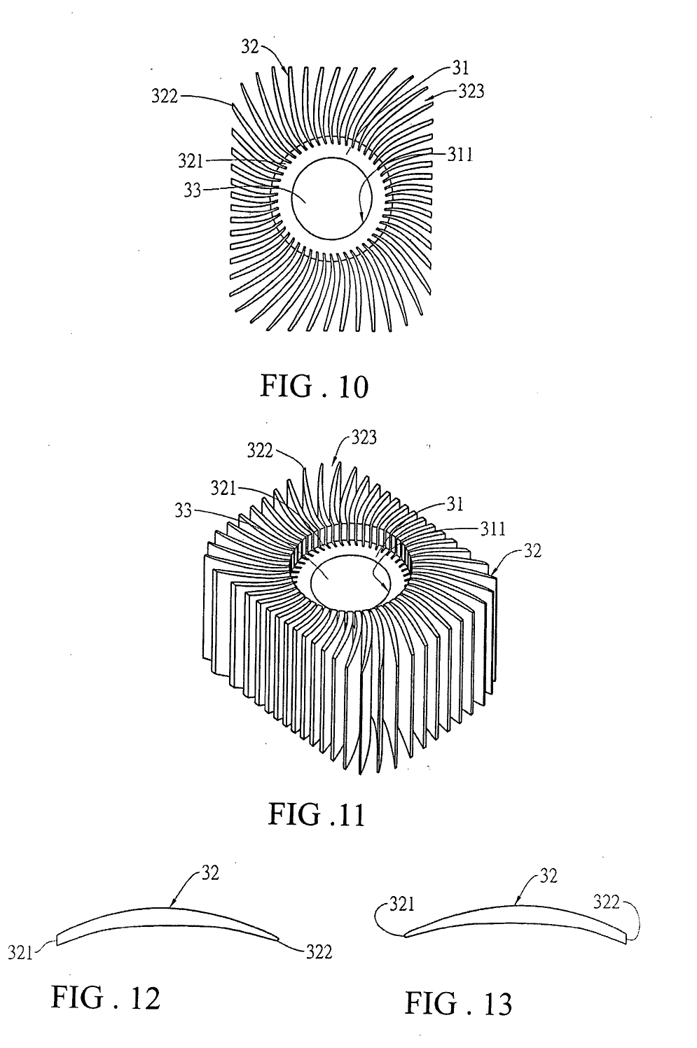

### DETAILED DESCRIPTION OF THE INVENTION

Referring to FIGS. 10 to 13, the first embodiment of a radiator unit for electronic components according to the present invention provides a main member 31 and a plurality of cooling fins 32. The main member 31 is cylindrical with a hollow center as shown in FIGS. 10 and 11 but it is noted that any other cross section geometries such as square and ellipse can be used instead of circular shape. The main member 31 has a hollow space 311 to tightly engage with post member 33, which has a shape and size the same as the hollow space 311. The cooling fins 32 extend along the perimeter of the main member 31 radially. The cooling fins 32 space apart a flow passage 323 to each other respectively. Each of the cooling fins 32 has a first end 321 connects with the perimeter of the main member 31 and a second end 322, which is the end extending outward and opposite to the first end 321. The first end 321 and the second end 322 have a curve respectively and provide a thickness different from each other, i.e., each of the cooling fins 32 is bent non-flatly. It is feasible that the thickness changes from the first end 321 toward the second end 322 as shown in FIG. 12 or from the second 322 toward the first end 321 as shown in FIG. 13. That is, each of the cooling fins 32 has a shape of wing and bends toward the same direction in the present embodiment. It is noted that, alternatively, each of the cooling fins 32 is capable of bending toward in different directions too. Further, each of the cooling fins 32 provides a length different from each other.

In addition, the main member 31 can be a solid cylinder instead of a cylinder with hollow center.

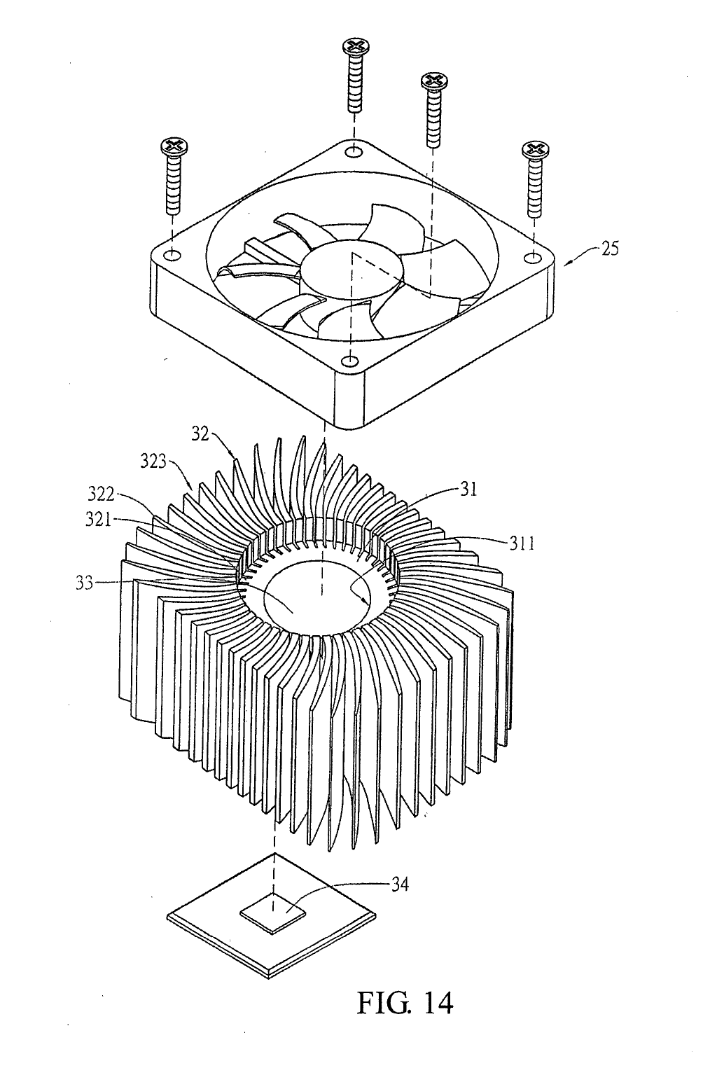

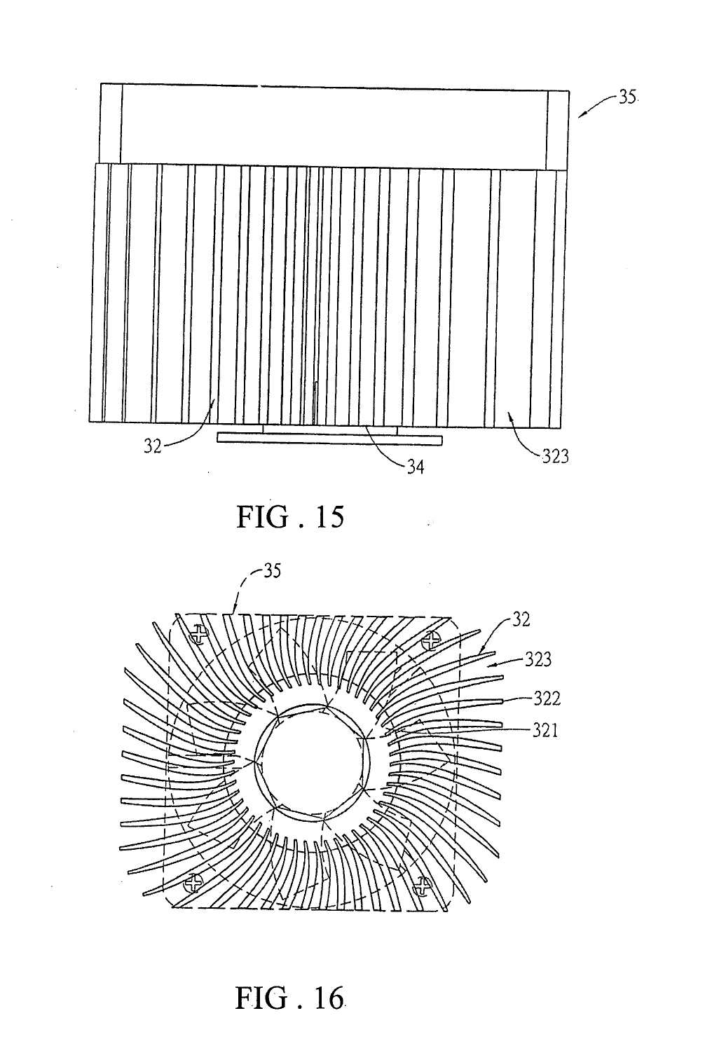

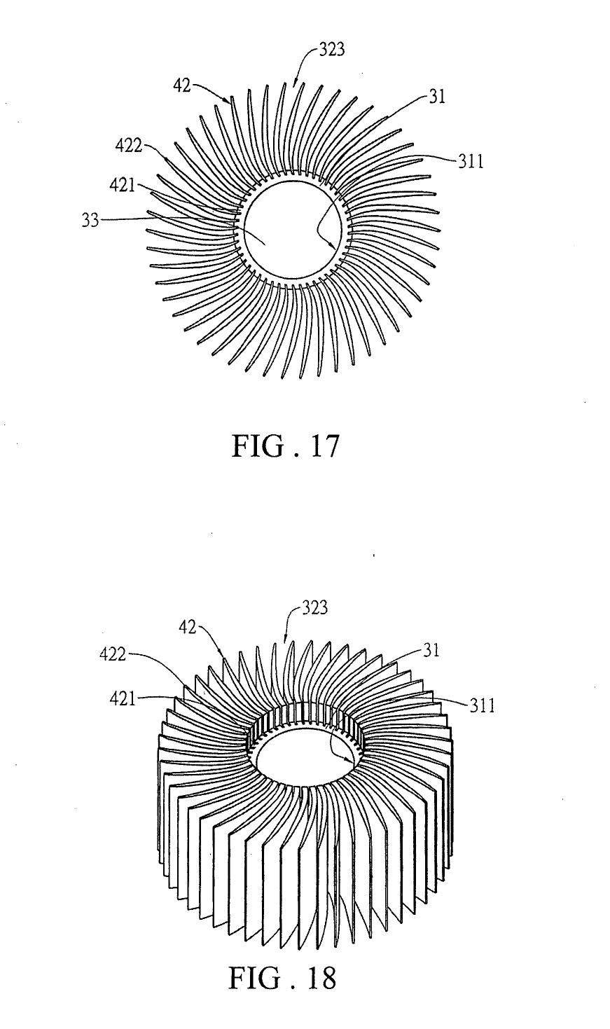

Referring to FIGS. 14, 15 and 16, a fan 35 is joined to the main member 31 for applying to an electronic component 34. It can be seen that the bottom of the main member 31 is attached to the surface of the electronic component 34 and the fan 35 is fixed to the top of the main member 31. The main member 31 conducts heat generated by the electronic component 34 to the cooling fins 32 and the fan 35 induces cold air to move toward the radiator. Once the cold air moves along the flow passage 323 between respective cooling fins 32, the cold air contacts with the surface of each of the cooling fins 32 to perform heat exchange with the heat transmitted by the cooling fins 32. When the air leaves the radiator to flow outward, the heat is carried with the air to reduce heat from the electronic component 34. Due to each of the cooling fins 32 being different in thickness from the first end 321 to the second end 322, the fluid from the fan 35 enters each of the cooling fins 32 against less resistance such that the fluid is able to move smoothly along the flow passage 323 and it enhances thermal flow energy and reduces thermal resistance value. In this way, problems existing in the conventional device are solved and noise resulting from impact of the fluid hitting the cooling fins 32 is reduced. Furthermore, heat dissipation area increases because of the number of cooling fins 32 being increased.

Referring to FIGS. 17 and 18, the second embodiment of a radiator unit for electronic components according to the present invention is illustrated. The integral structure and function are almost the same as the preceding embodiment. The identical parts are assigned the same reference numbers. The difference of the present embodiment is in that each of the cooling fins 42 provides the same length between the first end 421 and the second end 422.

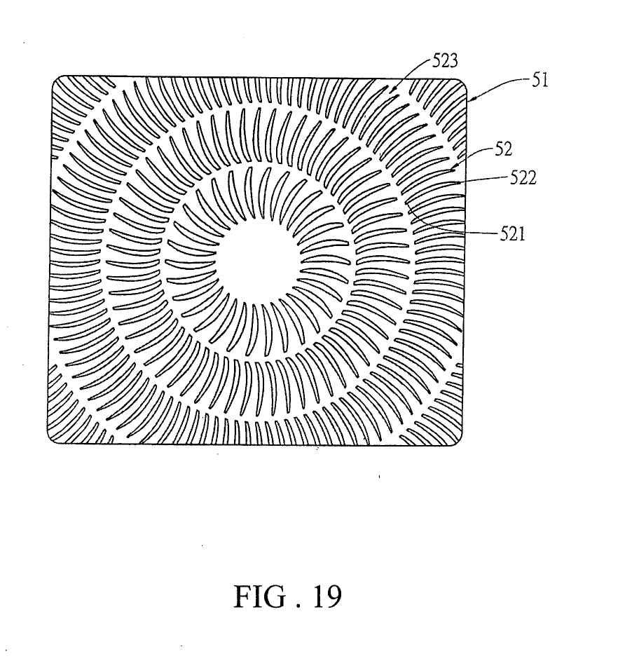

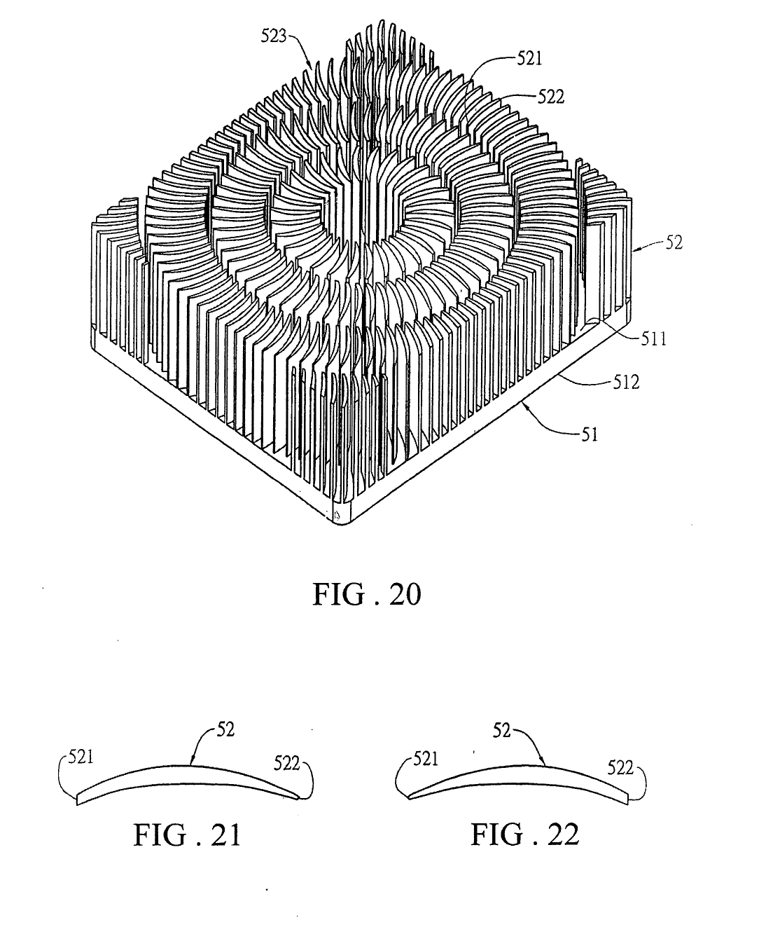

Referring to FIGS. 19 to 22, the third embodiment of a radiator unit for electronic components according to the present invention is illustrated. The radiator unit has a main member 51 and a plurality of cooling fins 52. The main member 51 has a first side 511 and a second side 512, which is opposite to the first side 511. The cooling fins 52 are mounted to the first side 511 and extend upward and each of the cooling fins 52 has a first end 521 and a second end 521, which is opposite to the first end 521. The first end 521 and the second end 522 have a curve respectively and provide a thickness different from each other, i.e., each of the cooling fins 52 is bent non-flatly. It is feasible that the thickness changes from the first end 521 toward the second end 522 as shown in FIG. 21 or from the second 522 toward the first end 521 as shown in FIG. 22. That is, each of the cooling fins 52 has a shape of wing and bends toward the same direction in the present embodiment. It is noted that, alternatively, each of the cooling fins 32 is capable of bending toward in different directions too.

The preceding cooling fins 52 in the present embodiment are arranged radially on the first side 511 of the main member 511 with a flow passage 523 being disposed to space apart each of the cooling fins 52 from another one of the cooling fins next to it respectively.

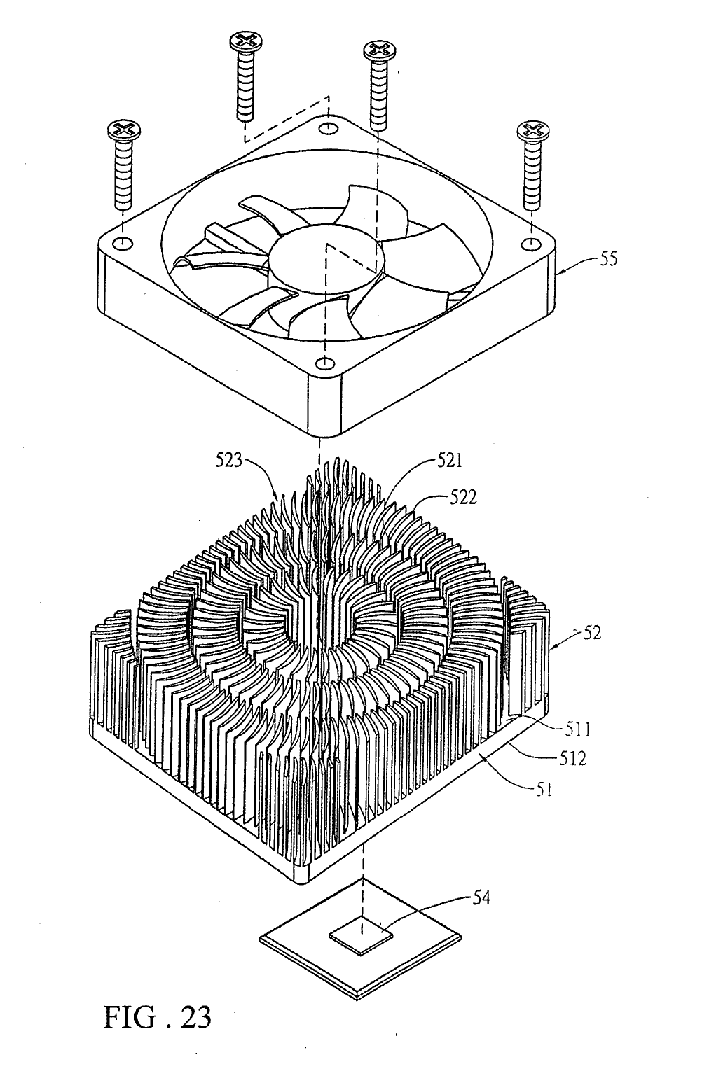

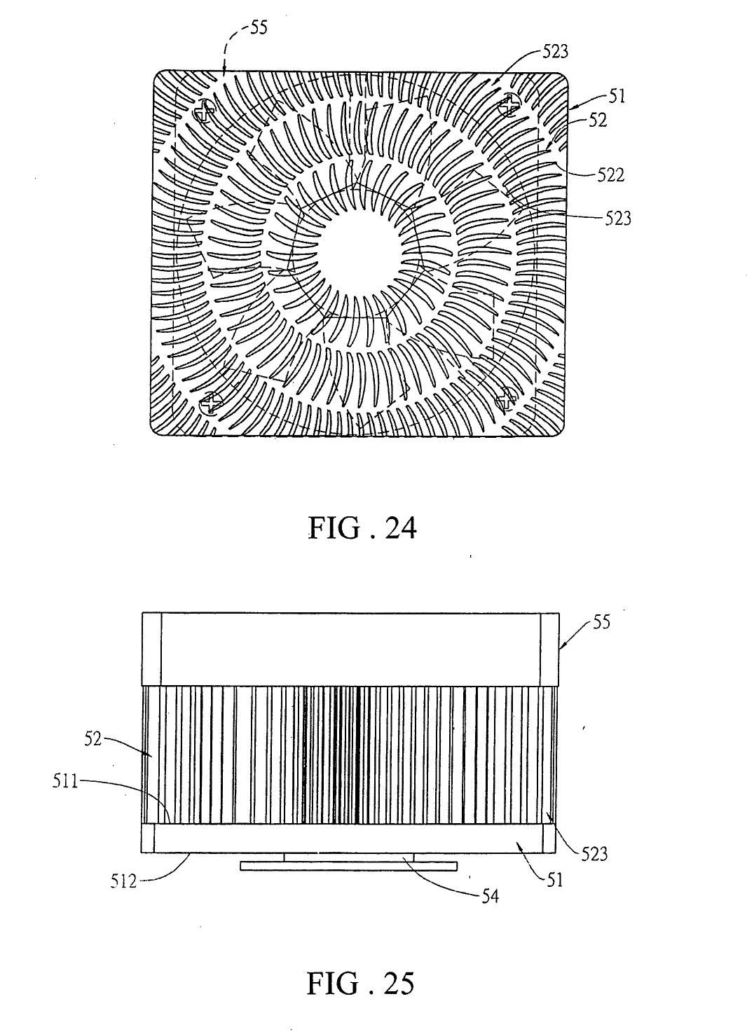

Referring to FIGS. 23, 24 and 25, a fan 55 is joined to the main member 51 for applying to an electronic component 54. It can be seen that the second side of the main member 51 is attached to the surface of the electronic component 54 and the fan 55 is fixed to the upward extending ends of the cooling fins 52. The main member 51 conducts heat generated by the electronic component 54 to the cooling fins 52 and the fan 55 induces cold air to move toward the radiator. Once the cold air moves along the flow passage 523 between respective cooling fins 32, the cold air contacts with the surface of each of the cooling fins 52 to perform heat exchange with the heat transmitted by the cooling fins 52. When the air leaves the radiator to flow outward, the heat is carried with the air to reduce heat from the electronic component 54. Due to each of the cooling fins 52 being different in thickness from the first end 521 to the second end 522, the fluid from the fan 35 enters each of the cooling fins 52 against less resistance such that the fluid is able to move smoothly along the flow passage 523 and it enhances thermal flow energy and reduces thermal resistance value. In this way, problems existing in the conventional device are solved and noise resulting from impact of the fluid hitting the cooling fins 52 is reduced. Furthermore, heat dissipation area increases because of the number of cooling fins 32 being increased.

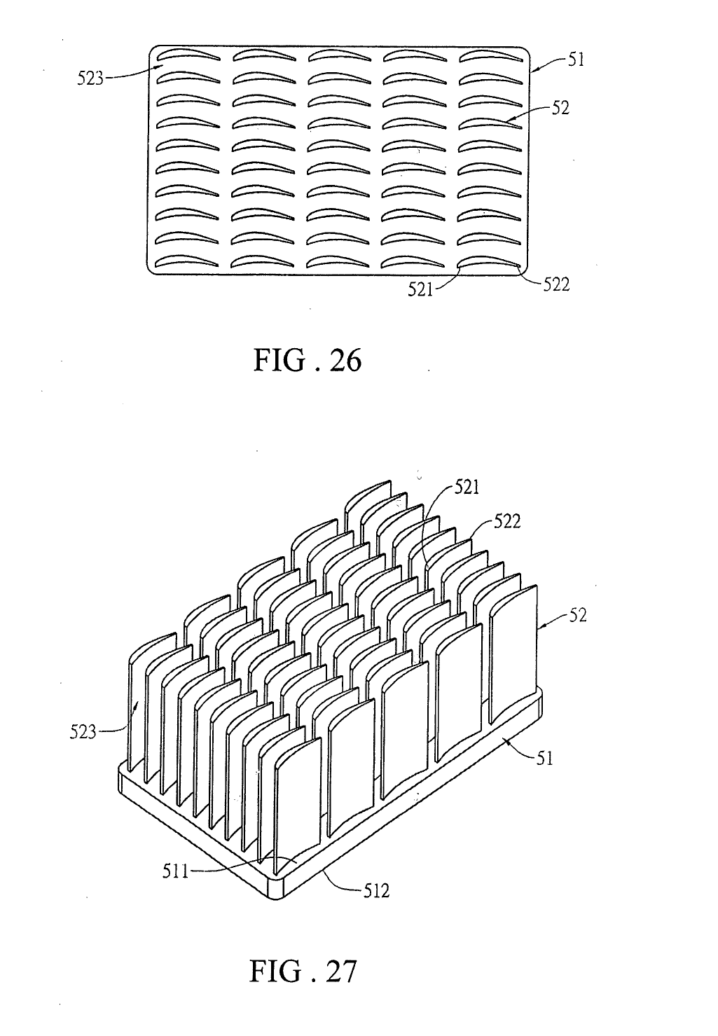

Besides, the cooling fins 52 are able to be distributed on the main member 51 as shown in FIGS. 26 and 27 except being arranged radially on the main member 51.

In addition, the cooling fins is capable of extending upward in equal lengths or different lengths and the length from the first end 521 to the second end 522 of each of the cooling fins 52 can be equal or different too.

While the invention has been described with referencing to preferred embodiments thereof, it is to be understood that modifications or variations may be easily made without departing from the spirit of this invention, which is defined by the appended claims.

What is claimed is:

1. A radiator unit for an electronic component, comprising:
a main member; and
a plurality of cooling fins, each of the cooling fins having a first end connecting with the perimeter of the main member and a second end extending outward in a radial direction with the thickness thereof being different from the first end to the second end.

2. The radiator unit for an electronic component as defined in claim 1, wherein each of the cooling fins bends from the first end to the second end.

3. The radiator unit for an electronic component as defined in claim 2, wherein each of the cooling fins bends toward the same direction.

4. The radiator unit for an electronic component as defined in claim 1, wherein each of the cooling fins has the same length.

5. The radiator unit for an electronic component as defined in claim 1, wherein each of the cooling fins is different in length.

6. The radiator unit for an electronic component as defined in claim 1, wherein the main member provides a hollow center.

7. The radiator unit for an electronic component as defined in claim 1, wherein the main member is solid.

8. A radiator unit for an electronic component, comprising:
a main member, providing at least a first side and a second side opposite to the second side; and
a plurality of cooling fins, being mounted to the first side, each of the cooling fins having a first end and a second end opposite to the first end with the thickness thereof being different from the first end to the second end.

9. The radiator unit for an electronic component as defined in claim 8, wherein each of the cooling fins bends from the first end to the second end.

10. The radiator unit for an electronic component as defined in claim 9, wherein each of the cooling fins bends toward the same direction.

11. The radiator unit for an electronic component as defined in claim 9, wherein each of the cooling fins bends toward different directions.

12. The radiator unit for an electronic component as defined in claim 8, wherein each of the cooling fins has the same length.

13. The radiator unit for an electronic component as defined in claim 8, wherein each of the cooling fins is different in length.

14. The radiator unit for an electronic component as defined in claim 8, wherein the cooling fins are mounted to the first side of the main member in a shape of matrix.

15. The radiator unit for an electronic component as defined in claim 8, wherein the cooling fins are mounted to the first side of the main member in a radial direction.
